(19) United States
(12) Patent Application Publication
(10) Pub. No.: US 2025/0046752 A1
(43) Pub. Date: Feb. 6, 2025

(54) MICRODEVICE CARTRIDGE STRUCTURE

(71) Applicant: VueReal Inc., Waterloo (CA)

(72) Inventor: Gholamreza CHAJI, Waterloo (CA)

(73) Assignee: VueReal Inc., Waterloo, ON (CA)

(21) Appl. No.: 18/696,429

(22) PCT Filed: Sep. 29, 2022
(86) PCT No.: PCT/CA2022/051444

§ 371 Date: Mar. 28, 2024

Related U.S. Application Data
(60) Provisional application No. 63/249,839, filed on Sep. 29, 2021.

(51) Int. Cl. H01L 23/00

(52) U.S. Cl. CPC H01L 24/95; H01L 2224/95001; H01L 2224/95136

(57) ABSTRACT

The present invention relates to relates to integrating microdevices into a system substrate using alignment and cartridges. The invention relates to transferring microdevices using alignment marks in a template substrate, aligning cartridges to the template substrate, placing the cartridges according to allocated positions in the template substrate, and transferring the cartridges to a holding substrate.

### BACKGROUND AND FIELD OF THE INVENTION

The present disclosure relates to integrating microdevices into a system substrate.

### BRIEF SUMMARY

According to one embodiment, there may be provided a method to transfer microdevices from a template substrate, the method comprising holding the microdevices in the template substrate, using alignment marks in a template substrate to align cartridges with a template substrate, aligning cartridges to the template substrate while the microdevices face the template substrate, placing the cartridges according to allocated positions in the template substrate, and transferring the cartridges to a holding substrate via a holding force in a close proximity.

### BRIEF DESCRIPTION OF THE DRAWINGS

The foregoing and other advantages of the disclosure will become apparent upon reading the following detailed description and upon reference to the drawings.

FIG. 1A shows a cross-section view of a micro device array on a micro device substrate, according to one embodiment of the present invention.

FIG. 1B shows a cross section view of micro device array with a buffer layer, according to one embodiment of the present invention.

FIG. 1C shows a cross section view of micro device array, according to one embodiment of the present invention.

FIG. 1D shows a cross section view of the micro device array bonded to an intermediate substrate, according to one embodiment of the present invention.

FIG. 1E shows a cross section view of the micro device array having pads, according to one embodiment of the present invention.

FIG. 2 shows a cross section view of a micro device array bonded to an intermediate substrate and a backplane, according to one embodiment of the present invention.

FIG. 3A shows process steps to extract position of microdevices, according to one embodiment of the present invention.

FIG. 3B shows modification in position/shape of electrode based on a position of micro devices, according to one embodiment of the present invention.

FIG. 3C shows providing extension to the electrodes, according to one embodiment of the present invention.

FIG. 4 A shows an exemplary microdevice embedded in a housing structure and release layer.

FIG. 4B shows an exemplary embodiment of microdevices confined in a block layers set on a release layer on top of a substrate.

FIG. 5 shows a process of using the blocked microdevices to form a template for transferring microdevices into a system backplane.

FIG. 6 shows one exemplary placement of blocks in a transfer template.

FIG. 7 shows process steps for forming a multi-device template using the blocked microdevices from different wafers to form a template for transferring microdevices into a system backplane.

FIG. 8 shows different microdevices from different substrates.

FIG. 9 shows pockets formed in a holding substrate.

FIG. 10A shows the cartridges aligned to a template substrate while the microdevices face the template substrate.

FIG. 10B shows a holding substrate e aligned with the template substrate and cartridges.

FIG. 11 shows a template (or transfer head) substrate.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

In this description, the term “device” and “micro device” are used interchangeably. However, it is clear to one skilled in the art that the embodiments described here are independent of the device size.

A few embodiments of this description are related to integration of micro-devices into a receiving substrate. The system substrate may comprise micro light emitting diodes (LEDs), Organic LEDs, sensors, solid state devices, integrated circuits, (micro-electro-mechanical systems) MEMS, and/or other electronic components.

LEDs or light emitting diodes may be for instance, Mini LEDs.

LEDs or light emitting diodes may be for instance, Mini LED lights.

LEDs or light emitting diodes may be for instance, miniature LEDs, which include chip, nano, and pico LEDs. These lights are extremely small and typically come in a single color or shape.

LEDs or light emitting diodes may be for instance, used for common applications where we see these miniature lights are in remote controls, calculators, and mobile phones.

LEDs or light emitting diodes may be for instance, are used for less complex design and minuscule size, these lights can easily be placed onto a circuit board without needing a device used to control heat.

LEDs or light emitting diodes may be for instance, Standard, Low-current, Ultra-high output LEDs.

LEDs or light emitting diodes may be for instance, application-Specific LEDs. LED lights can be constructed in a way to solve the specific needs of the device or user. Applications may be for instance (1) Lighting, (2) Alphanumeric, (3) RGB or Red Green Blue, (4) Bi-Color and Tricolor, and/or (5) Flashing.

LEDs or light emitting diodes may be for instance, High Power LEDs. The LEDs can have various luminosities, wavelengths and operate under various voltages.

LEDs or light emitting diodes may be for instance, have a device that helps utilize for heat control.

LEDs or light emitting diodes may be for instance, Alphanumeric LEDs displays.

LEDs or light emitting diodes may be for instance, Red Green Blue (RGB) LEDs.

LEDs or light emitting diodes may be for instance, Bi-Color and Tricolor.

The receiving substrate may be, but is not limited to, a printed circuit board (PCB), thin film transistor backplane, integrated circuit substrate, or, in one case of optical micro devices such as LEDs, a component of a display, for example a driving circuitry backplane. The patterning of micro device donor substrate and receiving substrate can be used in combination with different transfer technology including but not limited to pick and place with different mechanisms (e.g. electrostatic transfer head, elastomer transfer head), or direct transfer mechanism such as dual function pads and more).

In one embodiment, an array of micro devices may be developed on a micro device substrate, wherein the micro devices may be developed by etching of planar layers.

In another embodiments, an array of micro devices may be developed on a micro device substrate, wherein the micro devices may be developed chemical mechanical polishing of planar layers.

In another embodiment, a buffer layer is deposited on or over the array of micro devices. The buffer layer may be extended over the surface of the micro device substrate.

In another embodiment, a sacrificial layer is deposited on or over the array of micro devices. The sacrificial may be extended over the surface of the micro device substrate.

In some embodiments, one or more planarization layers may be formed on the micro device substrate and cured by one of: temperature, light or other sources.

In one embodiment, an intermediate substrate may be provided. In one case, bonding layers may be formed either on the intermediate substrate or over the planarization layers.

In another embodiment, the micro device substrate may be removed by laser or chemical liftoff.

In another embodiment, the micro device substrate may be removed by photoresist liftoff techniques.

In one embodiment, there may be an opening in the buffer layer that allows the micro devices to be connected to the planarization layer. In one case, an electrode may be provided on top or bottom of the planarization layer.

In another embodiment, after the micro device substrate is removed, extra process may be done. These processes comprises one of: removing extra common layers, thinning the planarization layer and or the microdevice, defect control steps, defect analysis steps, electrical tests, etc.

In one case, one or more pads may be added to the microdevices. The pads may be electrically conductive or purely for bonding to a system substrate. In one case, the buffer layer may connect at least one micro device to a test pad. The test pad may be used to bias the micro device and test its functionality. The test may be done at wafer level or at the intermediate (cartridge) level. The pad may be accessible at the intermediate (cartridge) level after removing the excess layers. The test pads can have any various shapes to measure an pad metallurgy properties.

In case the microdevice has more than one contact at the top side, the buffer layer may be patterned to connect the contacts of at least one of the microdevices to the test pads.

In another embodiment, a backplane may be provided. In one case, a backplane may have transistors and other elements for a pixel circuit to drive the microdevice. In another case, a backplane may be a substrate with no component.

In one embodiment, one or more pads may be provided on the backplane for bonding. In one case, the pads on the backplane or the pads on micro devices may create force to poll out the selected microdevices.

In another embodiment, after transferring the microdevices to the backplane, it is possible to detect the location/position of micro devices and adjust the patterning for other layers to match the misalignment in the transfer. In one case, different means may be used to detect the location of a micro device such as camera, probe tips, and etc. In another case, an offset in the transfer setup may be used to identify the misalignment in the position of the micro devices on the system substrate. In another case, color filter or color conversion may be adjusted based on the location of micro devices as well. In one case, some random offset may be induced in the micro device location to reduce the optical artifacts.

In one embodiment, patterns related to the micro devices may be modified (e.g., electrodes coupling micro devices to a signal, functional tunable layers (e.g., color conversion or color filter), via opening in the passivation/planarization layer, backplane layers, etc.).

In one case, a position/shape of an electrode may be modified based on the position of micro devices. In another case, there can be some extension for each electrode that its position or length can be modified based on the position of the micro device.

In one case alignment can be accomplished electrically.

In one case alignment can be accomplished using machine learning.

In one case alignment can be accomplished by having alignment marks on two layers and measuring their X and Y differences.

Various embodiments in accordance with the present structures and processes provided are described below in detail.

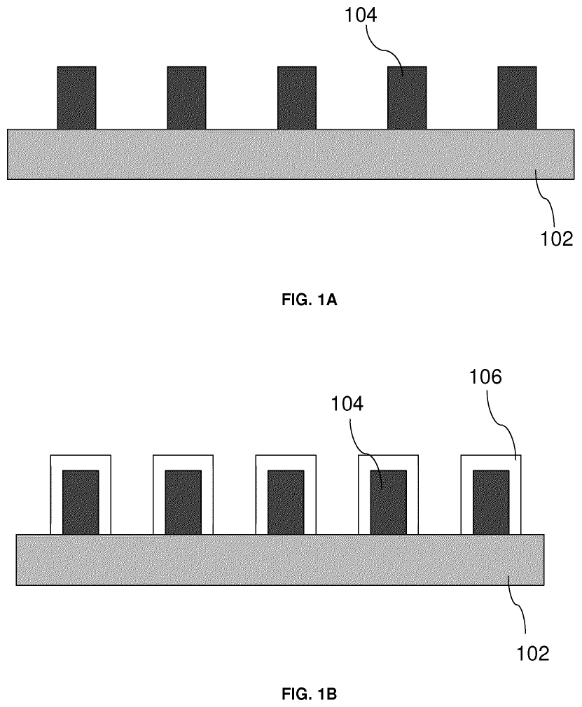

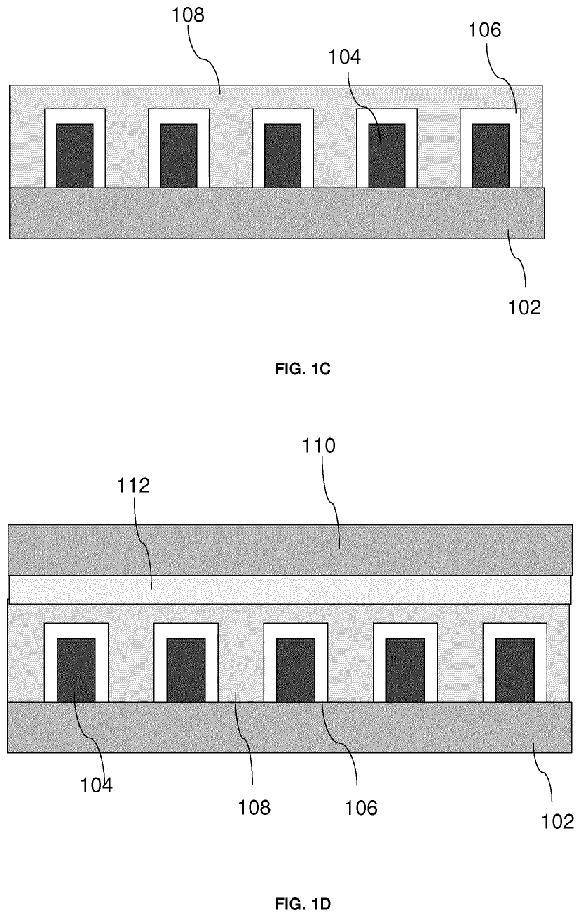

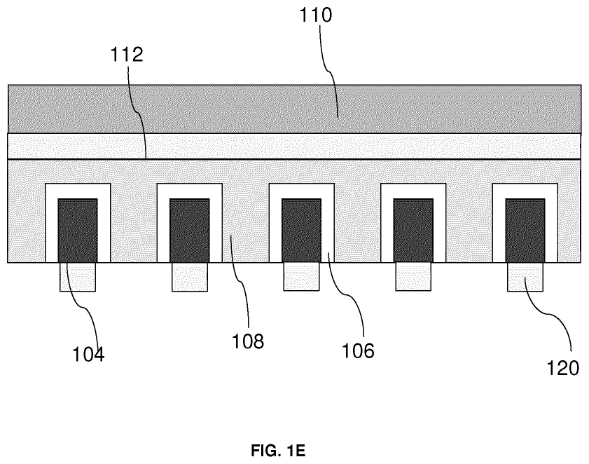

With reference to FIG. 1A, a micro device substrate 102 is provided. An array of micro devices 104 may be developed on the micro device substrate 102. In one case, the micro-devices can be micro light emitting devices. In another case, the micro devices may be any micro device that may typically be manufactured in planar batches, including but not limited to LEDs, OLEDs, sensors, solid state devices, integrated circuits, MEMS, and/or other electronic components. 104 may be transferred devices accomplished by transfer of devices on 102. In another embodiment micro devices may have been created on a first substrate (not shown) and then covered by a bonding layer (not shown) and then planarized surfacing micro devices 104 (not shown) then bonding to micro device substrate 102, to bonding layer, and tehn bonding layer and first substrate are removed (e.g., selective etching to micro device 104 and micro device substrate 102.

In one case, one or more planar active layers may form on a substrate. The planar active layers may comprise a first bottom conductive layer, functional layers, e.g., light-emitting devices, and a second top conductive layer. The micro devices may be developed by etching of the planar active layers. In one case, the etching may be done all the way to the micro device substrate. In another case, the etching may be done partially on the planar layers and leaving some on a surface of the micro device substrate. Other layers may be deposited and patterned before forming or after forming the micro devices.

With reference to FIG. 1B, a buffer layer 106 may be formed on the micro device substrate 102. The buffer layer 106 may be extended over the surface of the micro device substrate 102. The buffer layer may be conductive. The buffer layer 106 may include an electrode that can be patterned or be used as a common electrode. The buffer layer could be developed by first having the buffer layer on top of (and aligned to) each micro device 104 when micro devices 104 are formed. Then A second buffer layer is conformally coated on micro devices 104 and then directionally etched away, leaving buffer layer 106 on the top and sidewalls of microdevices 104.

With reference to FIG. 1C, a planarization layer 108 may be deposited on top of the micro device substrate 102 surrounding each micro device 104 for isolation and/or protection. The planarization layer may be cured. In one case, the planarization layer may be cured through one of temperature, light or by some other sources. The planarization layer may comprise a polymer. In one case, polyamide, SU8 or BCB may be used as polymers. In some cases the planarization layer may be a reflowed BPSG followed by Chemical Mechanical polish (CMP_to planarize. In some cases, the planarization layer can be CVD oxide followed by a CMP.

With reference to FIG. 1D, in one case, bonding layer(s) 112 may be formed on the planarization layer 108. The bonding layer(s) 112 may be the same or different as the planarization layer. In another case, the bonding layer(s) may be formed on top of an intermediate substrate (cartridge) 110. Bonding layer(s) may provide one or more of different forces such as electrostatic, chemical, physical, thermal or so on. The bonding layer 112 may come into contact with planarization layer 108 and after it is in contact with the planarization layer, it gets cured by either pressure, temperature, light or other sources. Bonding may be, for instance, Direct bonding, or Surface activated bonding, or Plasma activated bonding, or Anodic bonding, or Eutectic bonding, or adhesive bonding, or Thermocompression bonding, or reactive bonding.

In one embodiment, after forming an intermediate substrate 110 over the bonding layer, the micro device substrate 102 may be removed. The microdevice substrate 102 may be removed by laser or chemical liftoff. The microdevice substrate 102 may be removed by selective chemical etching.

In one case, there may be an opening in the buffer layer 106 that allows the micro devices 104 to be connected to the planarization layer 108. This would be accomplished by Reactive Ion directional etch (RIE) to etch the tops of buffer layer 106 off. This connection may act as an anchor. In one case, the buffer layer may be etched to form a housing, base or anchor at least partially surrounding each micro device. After lift-off, the anchor may hold the micro device to the substrate. In another case, the buffer layer may couple at least one of the microdevice pads to an electrode. The electrode may be placed on top or bottom of the planarization layer.

With reference to FIG. 1E, the micro device substrate may be removed to enable flexible system or post processing steps performed on the side of the system facing the substrate. After the substrate is removed, an extra process may be done. These processes comprises one of: removing extra common layers, thinning the planarization layer and/or the microdevice. In one case, one or more pads 120 may be added to the micro devices 104. In one case, these pads may be electrically conductive. In another case, these pads may be purely for bonding to a system substrate. In one case, buffer layer 106 may be conductive. In one embodiment, microdevices 104 are RIS back to an amount equal to connect to a pad. The gaps left in planarization layer 108 are used to form connections. This is done by a conformal metal deposited which fills the gaps. This is followed by CMP to remove all the metal except that which resides in the gaps. This forms a self-aligned connection to the micro devices 104.

In one embodiment, the buffer layer 106 may connect one or more micro devices to a test pad. The test pad may be used to bias the micro device and test its functionality. In one case, the test can be done at wafer/substrate level. In another case, the test may be done at the intermediate (cartridge) level. The pad may be accessible at the intermediate (cartridge) level after removing the excess layers. In another embodiment, a sacrificial metallization layer is formed for testing and then removed after testing.

In one case, if the microdevice has more than one contact at the top side, the buffer layer may be patterned to connect the contacts of at least one of the microdevices to test pads.

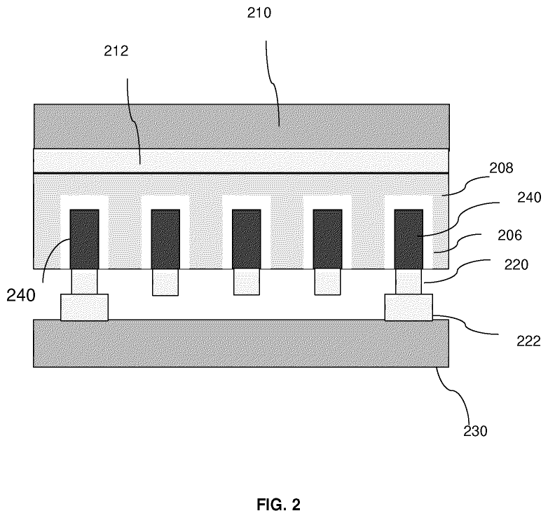

With reference to FIG. 2, a backplane 230 may be provided. In one case, the backplane may be made with a thin film transistor (TFT) process. In another case, the backplane may be made of chiplet fabricated with CMOS or other processes. In yet another case the backplane can contain transistors and other sensor (e.g., thermal) and devices (resistors, capacitors and inductors).

In one embodiment, the backplane may have transistors and other elements for a pixel circuit to drive the micro devices. In another embodiment, the backplane may be a substrate with no elements. One or more pads 222 may be formed on the backplane 230 for bonding the backplane to the micro devices array. In one case, the one or more pads on the backplane may be electrically conductive.

In one embodiment, the buffer layer 206 may be removed or deformed to release the micro devices. The pads 222 on the backplane or the pads 220 on micro devices may create force to pull out selected micro devices 240. In another embodiment, the buffer layer 206 or the housing may be etched back, reduced or removed. The housing may be removed from the empty LED spots. It should be noted that wherever pads 222 connect to micro devices 240, the micro devices remain after the buffer layer is removed, and those micro devices 204 that are not attached to pads 222 will be removed in the process.

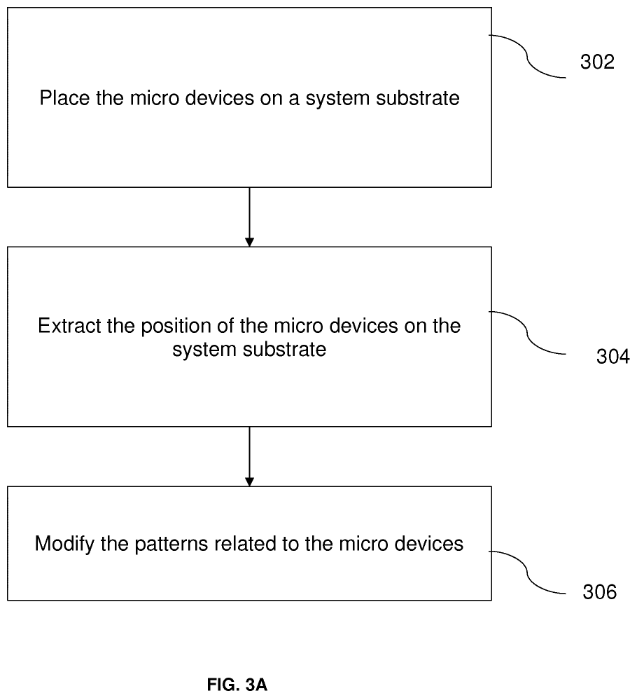

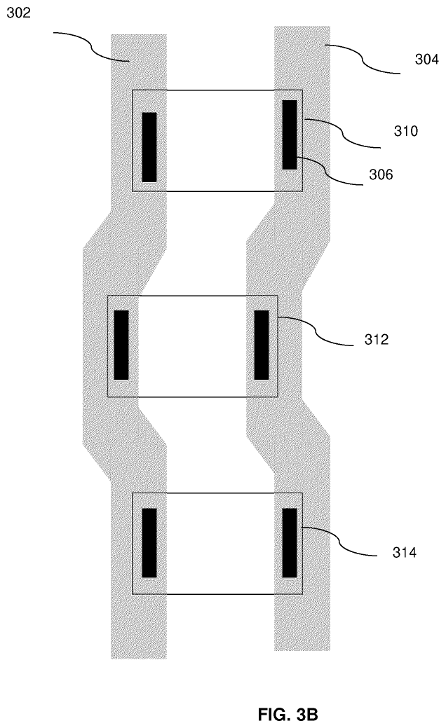

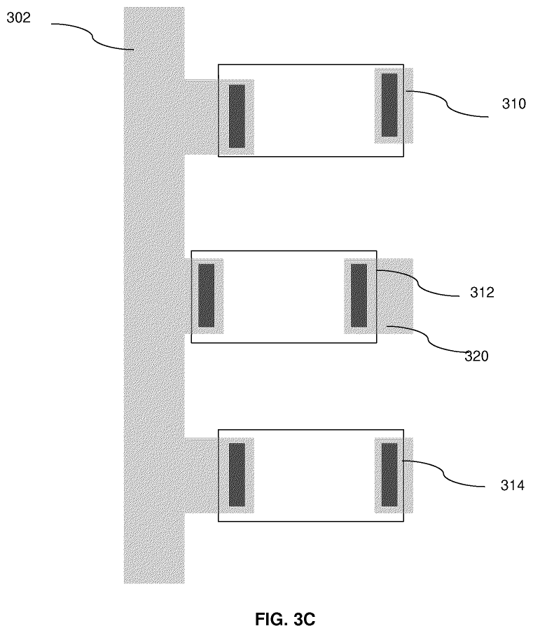

With reference to FIG. 3A, after transferring the microdevices to the backplane, a location of the micro devices on the backplane may be detected and in case of misalignment in the transfer, the patterning for other layers may be adjusted to match the misalignment in the transfer. The process steps comprising step 302, place the microdevices on a system substrate. At step 304, extract the position of the micro devices on the system substrate. Extracting the position of the micro device can be done by camera, surface profiler (optical, ultrasonic, electrical, etc.), or other means. At step 306, the patterns related to the micro devices may be modified. The patterns may include one of: electrodes coupling micro devices to a signal, functional tunable layers (e.g., color conversion or color filter), via opening in the passivation/planarization layer, backplane layers, etc. There can be some reference structure on system substrate to be used for calibrating the tool used for extracting micro device position first. or the reference can be used to find the relative position of micro devices.

In one embodiment there is an alignment mark formed of micro devices 240 as well as alignment marks formed on backplane 230, such that an optical measurement of the differences between alignment mark formed of micro devices 240 as well as alignment marks formed on backplane 230 will determine the offset in X and Y directions. This would be used to create the offsets necessary for subsequent processing of electrodes coupling micro devices to a signal, functional tunable layers (e.g., color conversion or color filter), via opening in the passivation/planarization layer, backplane layers, etc.

In one embodiment, different means may be used to detect the micro device's location. For example, camera, probe tips, and surface profiler (optical, ultrasonic, electrical etc.) or other means may be used to detect/extract the location/position of the micro device. In another embodiment, an offset in the transfer setup may be used to identify the misalignment in the position of the microdevices on system substrate/backplane.

For example, in one case, the metalization patterning may be done to avoid short or open. In another case, color filter or color conversion may be adjusted based on the location of microdevices as well. This can reduce the tolerance required for placement of microdevices. Some random offset may also be induced in the microdevice location to reduce the optical artifacts.

In one case, test structures can be added backplane 230 that when connected to test structures of micro devices 240, electrical tests can be used to determine the offset between backplane layer 230 and micro devices 240.

FIG. 3B shows modification in position/shape of electrode based on a position of micro devices, according to one embodiment of the present invention. One or more micro devices 310, 312 or 314 may be provided with contact pads 310. In one case, a position/shape of an electrode (302, 304) may be modified based on the position of micro devices (310, 212, 314). In another case, position/shape of the electrode may be modified based on a position of via. In another case, a position of via in planarization/passivation layer can be modified according to the micro device position.

In one embodiment, the electrodes 302, 304 shapes can be linear and parallel, but the contact hole shapes may be changed to suit connections.

FIG. 3C shows providing extension to the electrodes, according to one embodiment of the present invention. In one case, the position of the electrode 302 may be modified. Also, there can be some extension 320 for each electrode that its position or length can be modified based on the position of the micro device (310, 312 or 314). This can be used for common electrodes or individual electrodes.

According to one embodiment, there may be provided a method of integrating micro devices on a backplane comprising; providing a micro device substrate comprising one or more micro devices; bonding a selective set of the micro devices from the substrate to the backplane by connecting pads on the micro devices and corresponding pads on the backplane, leaving the bonded selective set of micro devices on the backplane by separating the micro device substrate.

According to other embodiment, the method may further comprise forming a buffer layer on or over the one or more micro devices extended over the substrate, forming a planarization layer on the buffer layer, depositing a bonding layer between the planarization layer and an intermediate substrate, curing the bonding layer after in contact with the planarization layer, removing the micro device substrate by one of: a laser or a chemical lift off.

According to some embodiments, the bonding layer is cured by either pressure, temperature or light.

According to other embodiments, the method may further comprise forming the pads on the micro devices through the buffer layer after removal of the micro device substrate, providing the corresponding pads on the backplane, wherein pads on the micro devices and corresponding pads on the backplane are electrically conductive.

According to yet other embodiments, bonding the selective set of the micro devices from the substrate to the backplane comprising the steps of: aligning and brining the microdevices and the backplane in contact; removing the buffer layer to release the micro devices; creating a force to pull out the selected set of micro devices; and bonding the selected set of micro devices to the backplane.

According to some embodiment, planarization layer may comprise a polymer, wherein the polymer is polyamide, SU8 or BCB. In some embodiments, the planarization layer may be formed of CVD oxide and the planarized using CMP.

According to other embodiments, the method may further include providing an opening in the buffer layer to allow the micro devices to connect to the planarization layer. The buffer layer is conductive, wherein the buffer layer connects at least one micro device to a test pad.

According to other embodiment, the method may further comprise providing an electrode either on a top or a bottom of the planarization layer, coupling at least one micro device to the electrode through the buffer layer, extracting position of micro devices on the backplane, extending a position of the electrode to extracting position of micro devices on the backplane, wherein the position of micro devices is extracted by one of: a camera, a probe tip, or surface profiler.

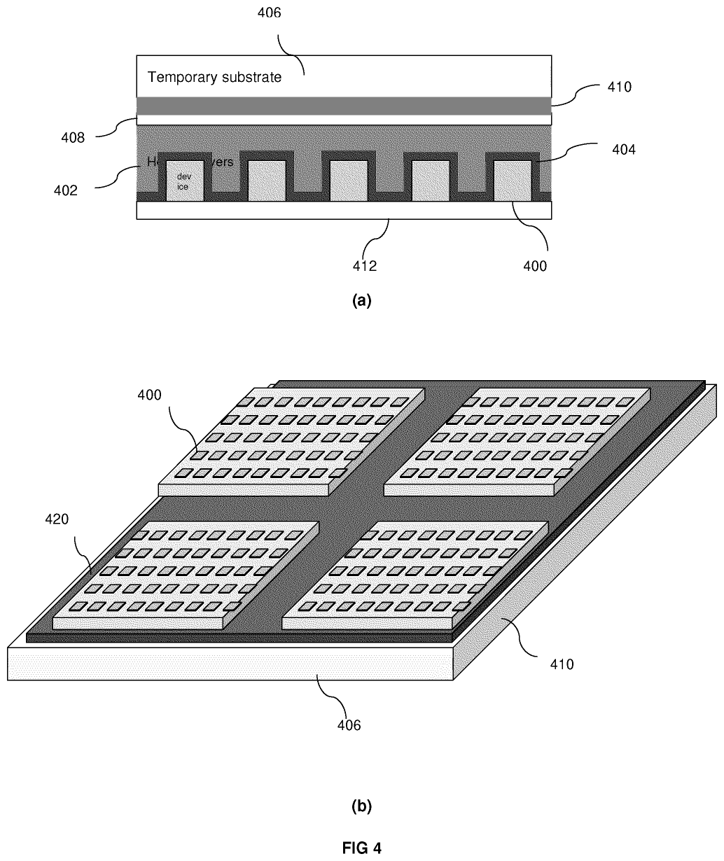

FIG. 4A shows an example of the micro devices 400 embedded in a housing structure 402 with a buffer layer 404. The structure is bonded to a temporary substrate 406 with a bonding layer 408. The bonding layer can be the same as the housing layer. There can be a release layer 410 between the housing structure and the temporary substrate 406. The bonding layer 408 can be the same as the release layer 410. There can be other layers on microdevice 400 such as bonding, pads, anchor and so on. These layers are demonstrated as layer 412. The buffer layer 404 is formed using CVD. The buffer layer 404 may be patterned and etched prior to housing structure 402 so that buffer layer will have maximum flexibility to connect to micro devices 400 as needed.

FIG. 4B shows an embodiment where the microdevices 400 are confined in blocks 420. These blocks 420 could be developed by singulating the housing layer(s) around a set of microdevices. Here, the release layer 410 can be patterned or be continuous. The housing materials can be different types of polymers (e.g., polyamide, BCB, SU8, Oxide or BPSG) or another dielectric.

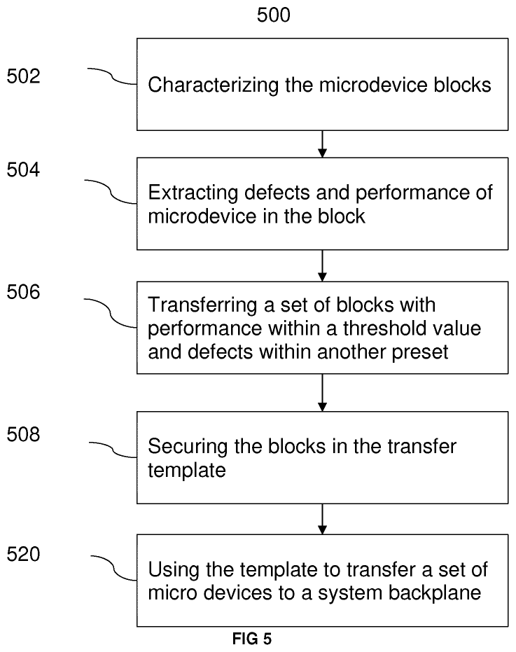

FIG. 5 shows a process 500 of using the blocked microdevices to form a template for transferring microdevices into a system backplane. During the first step 502, the microdevices in a block are characterized for at least one parameter. This characterization can be done through visual inspection, photo luminance, or electrical measurements. The extracted parameter can be either electrical, optical or other types. The blocks can be mapped based on the extracted parameter. A set of blocks that have met the threshold can be selected and transferred to a transfer template. The selection can be done based on the performance or defects in the blocks 506. Here the set of blocks are chosen if the defected micro devices in the block is smaller than a set threshold or the performance of the microdevices in that block is within a set threshold as well. Also the performance difference between the blocks is within threshold values. The transfer of the blocks to the template can be done by different processes. In one case, pick and place can be used. During the pickup process, the release layer is activated so that the block can be separated from the temporary substrate. Then the block is moved to the transfer template and placed on the template. The placing process can include bonding as well. The bonding step can be adhesive. After the set of blocks are transferred to the transfer template, the blocks can be secured in place 508. The process of securing can include curing, planarization, filler or other process steps.

In one embodiment, data at final testing of micro devices 400 can be related to data at this step, where machine learning could be used to correlate the two data's so that future thresholds can have a higher probability of passing final testing of micro devices 400.

The template can be used to transfer microdevices into a system backplane 520. In one approach the microdevices are directly transferred from the template into the system backplane. Here the template gets aligned with a part of the backplane. Then the selected set of microdevices in the template are placed on the backplane. The placement can be either by bonding, or laser separation. In another case, the microdevices are picked from the template and then transferred in the system backplane.

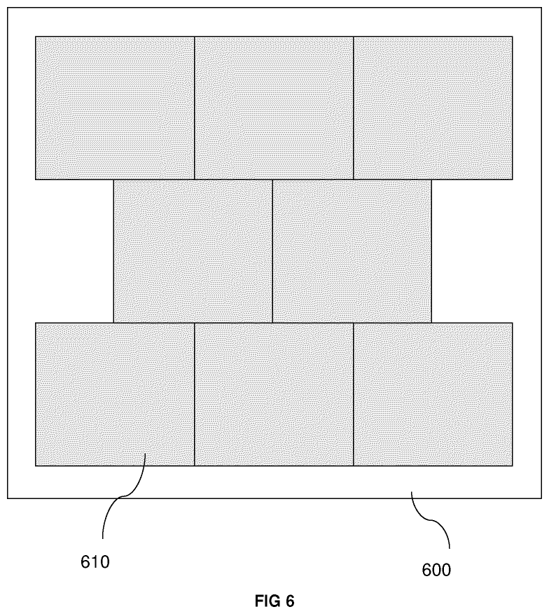

FIG. 6 shows one exemplary placement of blocks 610 in a transfer template 600. The skew in the blocks can be different or fixed. The skew can reduce some visual artifacts caused by the sharp edges. The templates also can have indentation in the edges. And the edges between the templates fit to the edge of the adjacent template.

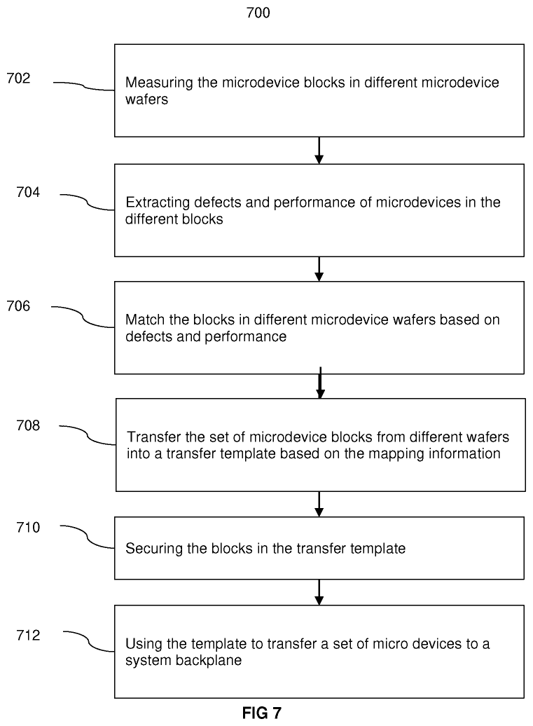

FIG. 7 shows process steps 700 for forming a multi-device template using the blocked microdevices from different wafers to form a template for transferring microdevices into a system backplane. During the first step 702 and 704, the block of microdevices in different wafers are characterized for at least one parameter. This characterization can be done through visual inspection, photo luminance, or electrical measurements. The extracted parameter can be either electrical, optical or other types. The blocks can be mapped based on the extracted parameters. A set of blocks from different wafers can be selected and transferred to a transfer template. The selection can be done based on the performance or defects in the blocks 706. Here the set of blocks are chosen if the defected micro devices in the block is smaller than a set threshold or the performance of the microdevices in that block is within a set threshold as well. Also, the performance difference between the blocks is within threshold values. The transfer of the blocks to the template can be done by different processes. In one case, pick and place can be used. During the pickup process, the release layer is activated so that the block can be separated from the temporary substrate. Then the block is moved to the transfer template and placed on the template. The placing process can include bonding as well. The bonding step can be adhesive. After the set of blocks are transferred to the transfer template, the blocks can be secured in place 708. The process of securing 710 can include curing, planarization, filler or other process steps.

In a further embodiment, all blocks of the lot of all wafers in stock are measured and are optimized for all final system backplanes to be produced in a lot, so that mapping can occur on all inventory before final selection.

The template can be used to transfer microdevices into a system backplane 712. In one approach the microdevices are directly transferred from the template into the system backplane. Here the template gets aligned with a part of the backplane. Then the selected set of microdevices in the template are placed on the backplane. The placement can be either by bonding, or laser separation. In another case, the microdevices are picked from the template and then transferred in the system backplane.

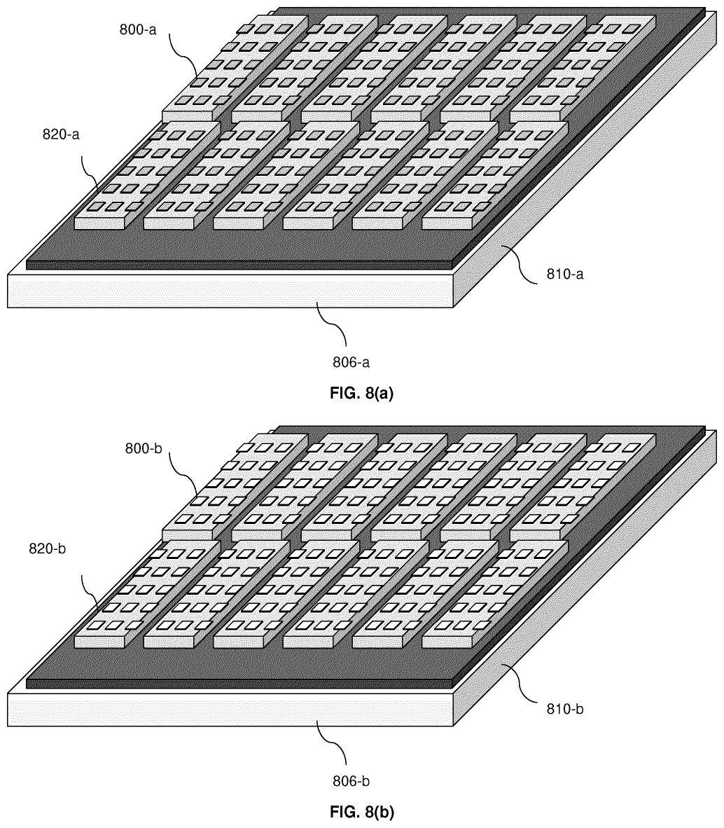

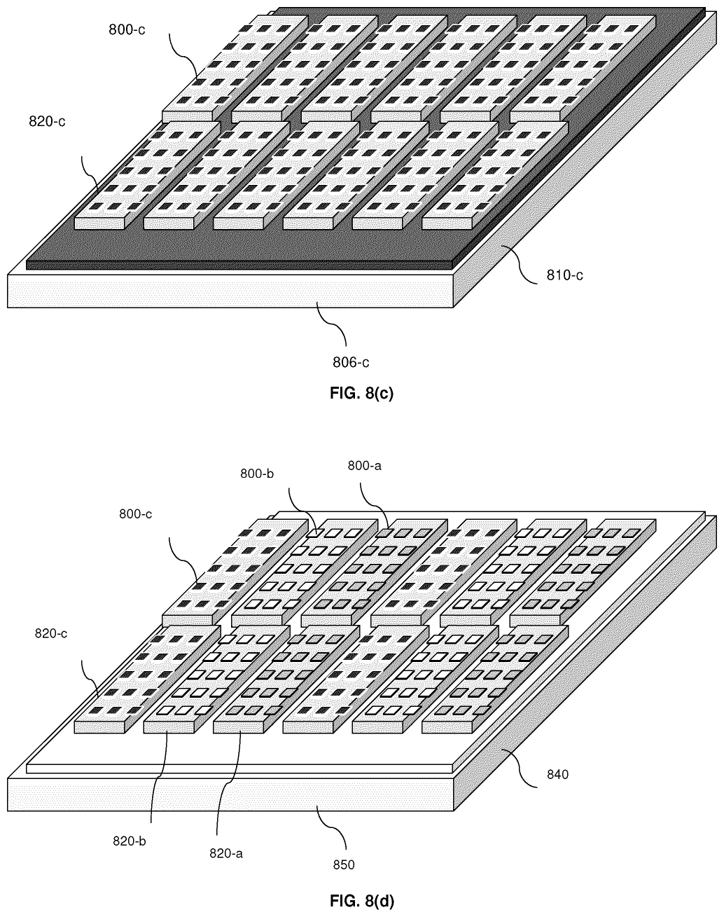

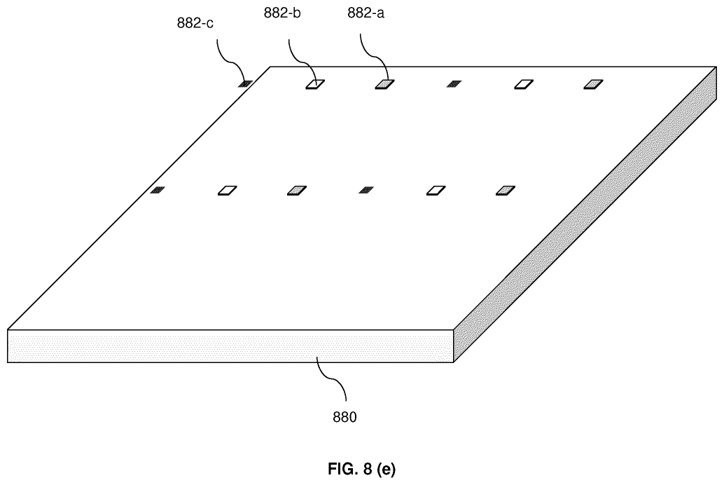

FIGS. 8(a)-(e) show different microdevices 800-a, 800-b, and 800-c from different substrates 806-a. 806-b and 806-c. The microdevices are embedded in blocks 820-a, 820-b and 820-c. A release layer 810-a, 810-b, and 810-c is used that can separate the microdevice blocks from the substrate. The release layers 810-a. 810-b, and 810-c can be patterned or cover the entire surface of the transfer template. The pattern can be the same as the block pattern. After mapping the microdevices, at least one block from each substrate 806-a, 806-b, and 806-c are transferred to the transfer template 850. There is a bonding layer 840 to hold the block on the transfer template. The template can be patterned to match the position of each block or it covers the entire transfer template. The blocks on the transfer template are placed to be in positions so it can correspond to the device positions 882-a, 882-b, and 882-c on system substrate 880.

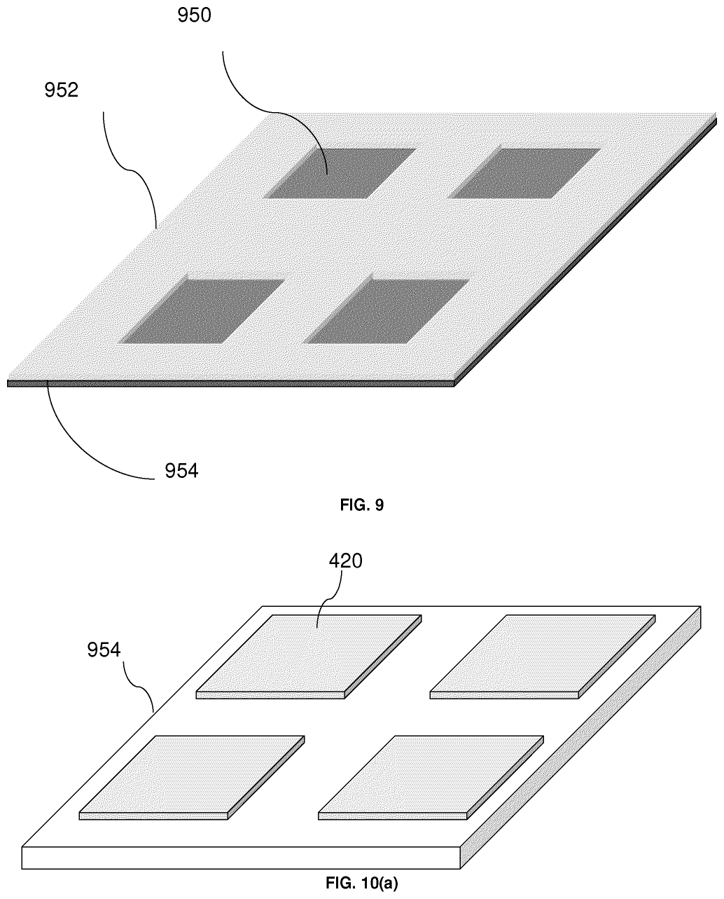

FIG. 9 shows another related embodiment. Here pockets 950 formed in a holding substrate 954. The sidewall 952 of the pockets 950 can be part of the substrate or a separate material deposited on the substrate 954 and turned into pocket by lithography patterning's, or etching patterning or lift off patterning processing. The housing substrates of FIG. 4 and FIG. 8 can be placed in the pockets. In one case, a template substrate is bonded to the housing substrates located in the pockets. The process can be repeated for several iterations to fill the template. In another related embodiment, the holding substrate holds the microdevices through a force (e.g., vacuum, electromagnetic, electrostatic, adhesive or other forces). The holding substrate can be used directly to transfer the microdevices in the housing substrate. Here the holding substrate is moved to the receiver/system substrate, it is aligned with the substrate, the microdevices are transferred into the receiver substrate. The process is repeated. When the microdevices are all transferred, the holding substrate can be loaded with the new housing substrate. In this case, pockets can be replaced with holding forces (e.g., vacuum, electrostatic, electromagnetic, etc.). In this case, the holding substrate is aligned with a housing substrate (Cartridge), the holding force for that substrate is activated. The housing is picked up. The process can be repeated to pick more than one housing substrate (Cartridge).

In a related case, the holding force can be an adhesive force. The adhesion can be temporary or permanently. In one case, the adhesive layer can be patterned as a single layer or islands for each housing layer. To minimize the impact of thermal expansion, the layer can be patterned to smaller pillars. In one case, the size and location of the pillar can match that of microdevices in the housing substrate. Here, the pillar can be also used as an alignment mark for picking the housing substrates.

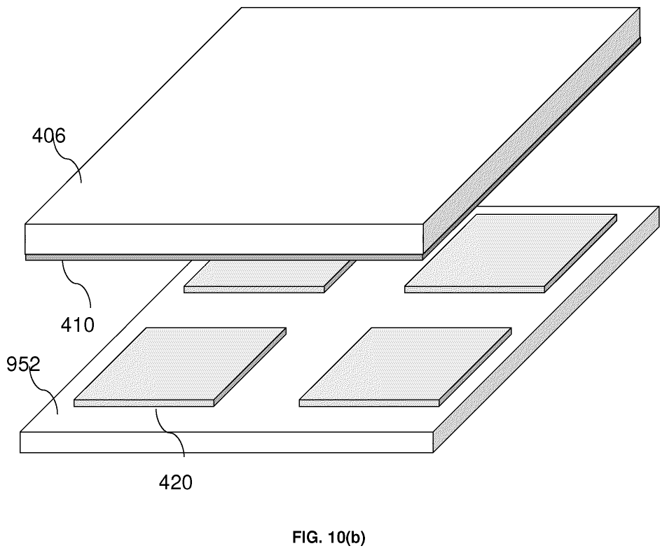

In another related embodiment, as shown in FIG. 10(a) the cartridges 420 are aligned to a template substrate 954 while the microdevices face the template substrate. There can be alignment marks in the template substrate or structures that can be used to align the cartridges with the template. The first cartridge is placed in the first position allocated for a cartridge in the template. The second cartridge is aligned with the second position in the template and it is placed in the second area. More than two cartridges can be placed on the template while the microdevices are facing the template surface. There can be a temporary bonding holding the cartridges to the template. In a related embodiment, there can be grooves in the template that fit the cartridge inside. The groove can be developed by different means such as etching. The cartridge can have an opposite structure on the surface that fits inside the grooves. As a result, the cartridge can stay on the surface. The grooves can be used as alignment marks as well.

As demonstrated in FIG. 10(b), a holding substrate 406 can be aligned with the template substrate 952 and cartridges 420. The holding substrate can have holding (pick up) force. It gets in close proximity (or contact) of the cartridges on the template and picks up the cartridges. The hold force can be an adhesive layer 410. The layer 410 can be patterned. The adhesive layer can be cured by temperature, light or other means. Another related holding force can be vacuum. There can be a vacuum force in places associated with each cartridge in the holding substrate 406 that picks the cartridges from the template 952. In another related embodiment, the layer 410 can be a deformable layer to compensate for some surface non-uniformity of the cartridges. In another related embodiment, there can be a gimbal in places associated for each cartridge in holding substrate 406. The gimbal can adjust the surface profile to compensate for the cartridge tilt or surface flatness non-uniformity. The holding substrate 406 can move to a system substrate and transfer the microdevices selectively to the system substrate as described in other related embodiments.

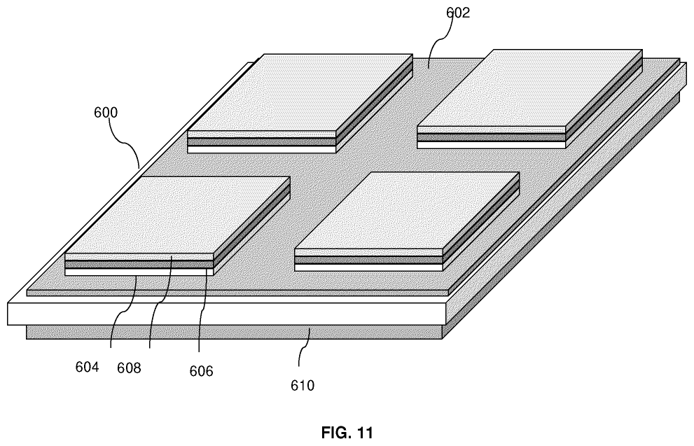

In one related embodiment, soft material is added to the template, transfer head or cartridge to compensate for some of the surface non-uniformity. FIG. 11 shows a template (or transfer head) substrate 600. In one related embodiment, there is soft material 602 between the template (or transfer head) 600 and cartridge substrate 604. The soft material can be covering part or all the interface between the template (or transfer head) 600 and the cartridge substrate 604. The template (or transfer substrate) can be made of multiple layers and may include forces to hold the cartridge substrate. The force can be vacuum, adhesive, electrostatic, or other type. Cartridge substrate 604 can be made of multiple layers. One of the layers 606 can be soft materials that can deform under pressure to compensate for surface non-uniformity. The cartridge substrate includes micro device layer 608 that includes at least an array of microdevices that can be transferred from the cartridge substrate 604 to a system substrate. In another related embodiment, the template substrate (or transfer head) 600 is on a soft material layer 610. The soft material layer can be PDMS, graphite, or other types. In one related embodiment, the template or transfer head brings the array of microdevices 608 on the cartridge substrate 604 to a system substrate. Pressure is applied to bond a selective set of micro devices to the system substrate. In case of the surface profile non-uniformity, the soft material incorporated in the structure can deform to compensate for the surface non-uniformity and as such make sure all the selected micro devices are in contact with the system substrate and get bonded to it.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

We claim:

1. A method to transfer microdevices from a template substrate, the method comprising:
providing cartridges;
holding the microdevices in the template substrate;
using alignment marks in a template substrate to align cartridges with a template substrate;
aligning cartridges to the template substrate while the microdevices face the template substrate;
placing the cartridges according to allocated positions in the template substrate; and
transferring the cartridges to a holding substrate via a holding force in a close proximity.

2. The method of claim 1, wherein the holding force is an adhesive force.

3. The method of claim 2, wherein the adhesive force is an adhesive layer.

4. The method of claim 1, wherein there is a temporary bonding to hold the cartridges to the template.

5. The method of claim 1, wherein there are grooves in the template substrate that fit the cartridge inside.

6. The method of claim 5, wherein the grooves can be developed by different means such as etching.

7. The method of claim 5, wherein the cartridges have an opposite structure on the surface that fits inside the grooves such that cartridges can stay on a surface.

8. The method of claim 5, wherein the grooves are used as alignment marks.

9. The method of claim 3, wherein the adhesive layer is cured by temperature, light or other means.

10. The method of claim 3, wherein the adhesive layer is patterned.

11. The method of claim 1, wherein the holding force is a vacuum.

12. The method of claim 11, wherein there is a vacuum force in places associated with each cartridge in the holding substrate that picks the cartridges from the template substrate.

13. The method of claim 3, wherein the adhesive layer is a deformable layer to compensate for some surface non-uniformity of the cartridges.

14. The method of claim 1, wherein there is a gimbal in places associated for each cartridge in the holding substrate.

15. The method of claim 14, wherein the gimbal adjusts a surface profile to compensate for a cartridge tilt or a surface flatness non-uniformity.

16. The method of claim 1, wherein the holding substrate is moved to a system substrate and transfers the microdevices selectively to the system substrate.

17. The method of claim 1, wherein there is a soft material between the template substrate and the cartridge.

18. The method of claim 17, wherein the soft material covers part of or full interface between the template substrate the cartridge substrate.

19. The method of claim 18, wherein the template substrate is made of multiple layers including forces to hold the cartridge.

20. The method of claim 19, wherein the force is either vacuum, adhesive, or electrostatic.

21. The method of claim 19, wherein the cartridge is made of multiple layers wherein further one of the layers is a soft material that deforms under pressure to compensate for a surface non-uniformity.

22. The method of claim 21, wherein the cartridge includes a microdevice layer that includes at least an array of microdevices that are transferred from the cartridge to a system substrate.

23. The method of claim 22, wherein the template substrate is on a soft material layer which is with PDMS or graphite.

24. The method of claim 21, wherein the template substrate brings the array of microdevices on the cartridge substrate to a system substrate.

25. The method of claim 24, where a pressure is applied to bond a selective set of microdevices to the system substrate.

26. The method of claim 25, where in case of the surface profile non-uniformity, the soft material incorporated in the structure deforms to compensate for the surface non-uniformity to allow all the selected micro devices to be in contact with the system substrate and get bonded to it.

27. The method of claim 1, where the alignment marks are calculated using machine learning.

28. The method of claim 1, where the micro devices are any type of LED.

29. The method of claim 1, where the micro devices contain sensors.

30. The method of claim 1, where the micro devices contain passive circuit elements.

31. The method of claim 1, where the micro devices contain test structures.
